(19) United States
(12) Patent Application Publication
(10) Pub. No.: US 2004/0185599 A1
(43) Pub. Date: Sep. 23, 2004

(54) Method for fabricating a semiconductor component based on a nitride compound semiconductor

(76) Inventors: Volker Harle, Waldetzenberg (DE); Alfred Lell, Maxhutte-Haidhof (DE); Andreas Weimer, Regensburg (DE)

Correspondence Address: LERNER AND GREENBERG, P.A., POST OFFICE BOX 2480, HOLLYWOOD, FL, 33022-2480, US

(21) Appl. No.: 10/813,530

(22) Filed: Mar. 29, 2004

Related U.S. Application Data
(63) Continuation of application No. PCT/DE02/03667, filed on Sep. 27, 2002.

(30) Foreign Application Priority Data
Sep. 27, 2001 (DE) 101 47 791.0

(51) Int. Cl. H01L 21/00; H01L 21/44

(52) U.S. Cl. 438/98; 438/93; 438/46

(57) ABSTRACT

A method for fabricating a semiconductor component is based on a nitride compound semiconductor. In a first step of the method, provision is made of a semiconductor body containing at least one nitride compound semiconductor. In a second step, a metal layer is applied to the surface of the semiconductor body. Afterward, in a third step, the semiconductor body is patterned, a part of the metal layer and parts of the underlying semiconductor body are removed.

### CROSS-REFERENCE TO RELATED APPLICATION

This application is a continuation, under 35 U.S.C. § 120, of copending international application No. PCT/DE02/03667, filed Sep. 27, 2002, which designated the United States; this application also claims the priority, under 35 U.S.C. § 119, of German patent application No. 101 47 791.0, filed Sep. 27, 2001; the prior applications are herewith incorporated by reference in their entirety.

### BACKGROUND OF THE INVENTION

### FIELD OF THE INVENTION

The invention relates to a method for fabricating a semiconductor component based on a nitride compound.

Semiconductor components of the aforementioned type have a semiconductor body containing a nitride compound semiconductor. In this case, a nitride compound semiconductor is to be understood as, in particular, a nitride compound having elements of the third and/or the fifth group of the Periodic Table of the Elements. Examples of these are compounds such as GaN, AlGaN, InGaN, AlInGaN, AlN and InN, which can be summarized by the formula Al_{y}InₓGa_{1-x-y}N, 0≦x≦1, 0≦y≦1, 0≦x+y≦1.

The fabrication of such semiconductor components generally requires the formation of contact areas on the surface of the semiconductor body, the contact areas usually are embodied as metal layers.

In this case, the contact resistance formed between the contact layer and the semiconductor body is intended to be as low as possible since the power dropped across the contact resistance is converted into heat loss and is not available for functional operation, for example for radiation generation in the case of a radiation-emitting component. Moreover, it is necessary to provide for a sufficient dissipation of the heat loss in order to avoid an excessively great increase in temperature of the component. There is otherwise the risk of thermally induced damage to the component.

In the case of gallium-nitride-based components, comparatively high contact resistances arise primarily in the case of p-doped semiconductor regions in conjunction with a metal layer. It has furthermore been found that high contact resistances occur in particular in the case of patterned semiconductor surfaces, for example in the case of ridge waveguide structures.

Ridge waveguide structures of this type are disclosed for example in the reference titled “Properties, Processing and Applications of Gallium Nitride and Related Semiconductors”, EMIS Datareviews Series No. 23, J. H. Edgar, S. Strite (ed.), Inspec 1999, pp. 616-622, which describes a semiconductor laser having a semiconductor body with a layer sequence which contains a plurality of GaN and AlGaN layers and also an InGaN multiple quantum well structure. The layer sequence is applied to a SiC substrate. An elongate, parallelepiped-like ridge structure is shaped from the semiconductor body on the side remote from the substrate ,the ridge structure being provided with a contact metallization on the topside. The ridge structure forms a waveguide for guiding the radiation field generated in the semiconductor body.

In order to form such a ridge structure, it is usually the case that first a semiconductor body with an unpatterned surface is fabricated, from which regions which laterally adjoin the ridge to be formed are subsequently removed by an etching method. The semiconductor body may then be provided with a passivation layer, if appropriate. Finally, the contact metallization is applied.

U.S. Pat. No. 6,130,446 describes an etched nitride semiconductor structure, in the case of which, after the patterning etching of a p-GaN semiconductor layer, a p-type contact is applied to the surface thereof. On account of alignment and etching tolerances, in order to avoid a short circuit of the pn junction, the p-type contact must be smaller than the surface of the assigned p-GaN semiconductor layer. This is disadvantageous, however, with regard to a component resistance that is as low as possible.

Japanese Patent JP 2000-188440 describes a GaN semiconductor configuration which is provided for upside-down mounting and in the case of which an Ni contact layer is first masked and etched wet-chemically and the p-GaN layer is dry-etched through etched openings in the Ni contact layer for patterning purposes. This method leads to inclined etching sidewalls of the semiconductor structure.

### SUMMARY OF THE INVENTION

It is accordingly an object of the invention to provide a method for fabricating a semiconductor component based on a nitride compound semiconductor which overcomes the above-mentioned disadvantages of the prior art methods of this general type, in which the semiconductor component has a contact layer with an improved, in particular lower, contact resistance.

With the foregoing and other objects in view there is provided, in accordance with the invention, a method for fabricating a semiconductor component. The method includes the steps of providing a semiconductor body containing a substrate and at least one nitride compound semiconductor disposed on the substrate, applying a metal layer to a surface of the semiconductor body, and dry-chemically removing a part of the metal layer and a part of the semiconductor body previously covered by the removed metal layer.

It is provided that, in a first step, a semiconductor body containing a nitride compound semiconductor is provided, a metal layer being applied to the surface of the semiconductor body in a second step. In a third step, the surface of the semiconductor body is patterned, a part of the metal layer and a part of the underlying semiconductor body being removed. Preferred nitride compound semiconductors are, in particular, compounds having the formula Al_{y}InₓGa_{1-x-y}N, 0≦x≦1, 0≦y≦1, 0≦x+y≦1.

The method has the advantage that a metal layer is applied to the semiconductor body as early as before the patterning, which metal layer may subsequently serve as a contact layer or as part of a contact layer.

The method is particularly preferably used for fabricating a low-resistance p-type contact, a self-aligning bottommost p-type contact layer and, preferably at the same time, a dielectric etching auxiliary mask applied above the p-type contact being used. A p-type connection layer (e.g. connection metallization) is applied before the etching of the semiconductor material and both the underlying p-type contact layer and the p-type nitride semiconductor layer are patterned chemically, in particular dry-chemically, in one (or more) successive method steps.

In particular with the aid of a dielectric auxiliary mask (e.g. made of silicon (di)oxide), aluminum oxide and/or titanium oxide) between a photoresist layer and a metal layer, a layer arises which is highly resistant to etching from a dry-chemical standpoint and, as masking, entails the advantage of very steep ridge structures. In the case of laser ridge structures, the advantage of steep laser ridge structures is combined with ideal wave-guiding properties.

In the case of the method, the p-type metal layer and the p-type nitride semiconductor layer are patterned in one or at least in directly successive etching steps, in particular dry etching steps. This is a self-aligning process. The entire p-type nitride semiconductor structure is advantageously completely metallized.

With the method, the entire surface of a p-type nitride semiconductor structure that is available for electrical connection is completely metallized in conjunction with very steep sidewalls of the p-type nitride semiconductor structure.

The method according to the invention makes it possible, in the case of a laser ridge, to achieve at the p-type contact connection area thereof (surface of the laser ridge) virtually the same ridge widths as at the wave-guidance-determining ridge base (lower edge of the laser ridge). The method according to the invention offers, in particular on GaN and related materials, a maximum possible connection area on a p-conducting surface.

It has been found that during the patterning of the semiconductor body, impurities can penetrate into the semiconductor body or accumulate on the surface thereof. If a contact metallization is subsequently applied to the surface, then electrical properties of the contact thus formed, in particular the contact resistance, may be impaired or increased by the impurities. The invention achieves an advantageously low contact resistance since the application of the metal layer before the patterning prevents or at least reduces a penetration of impurities into the metal-semiconductor boundary region.

A mask technique is preferably used for partly removing the metal layer and the underlying semiconductor body. For this purpose, a suitable mask adapted to the later removal method is applied to the metal layer, which mask may contain a silicon oxide, for example. The mask itself is preferably formed by a conventional photolithographic method, the regions of the metal layer that are to be removed not being covered with the mask.

Afterward, first the regions of the metal layer that are not covered by the mask are removed, thereby uncovering the underlying semiconductor surface. By way of example, etching methods or sputtering-back methods are suitable for removing the metal layer.

Afterward, the semiconductor body is partly removed in regions of the uncovered semiconductor surface. An etching method, for example reactive ion etching (RIE) or a wet-chemical etching method, will likewise be used for this purpose. Finally, the mask is removed.

Both during the removal of the metal layer and during the removal of the semiconductor body, those regions of the metal layer and of the underlying semiconductor body which are covered by the mask remain essentially uninfluenced, apart from effects at the removal sidewall.

In an advantageous development of the invention, after the patterning of the semiconductor body, a passivation layer is applied to the semiconductor surface and, if appropriate, to the metal layer. The passivation layer serves as a protective layer for the underlying semiconductor surface.

Preferably, a contact metallization is subsequently formed on the metal layer, which contact metallization may also cover the passivation layer. The contact metallization serves, in particular, for improving and optimizing the connection properties (bonding properties) of the contact layer. For this purpose, the contact metallization may contain for example materials, generally metals, which enable a mechanically stable wire connection with high electrical conductivity. Furthermore, the contact metallization may have laterally larger dimensions than the metal layer, thereby facilitating the lateral positioning of a wire connection. In this case, the passivation layer is advantageously simultaneously used as electrical insulation between the contact metallization and the semiconductor surface.

In this embodiment, it is expedient to form the passivation layer in such a way that at least parts of the metal layer are not covered with the passivation layer, so that the subsequently applied contact metallization directly adjoins the metal layer in these uncovered regions and a contact having good electrical conductivity is formed between the metal layer and the contact metallization.

Preferably, a mask technique is likewise used for applying and shaping the passivation layer. In this case, first a continuous passivation layer is applied to the semiconductor surface and the metal layer. The continuous passivation layer is provided with a mask, the passivation layer remaining uncovered in regions in which it adjoins the metal layer. Afterward, the uncovered parts of the passivation layer are removed, for example by an etching method, and the mask is finally removed. The mask itself may once again be fabricated photolithographically.

In the case of semiconductor lasers based on nitride compound semiconductors, the method according to the invention may advantageously be used for fabricating ridge waveguide structures. Semiconductor lasers are operated with comparatively high currents and moreover require, with regard to their optical properties, an operating temperature that is as constant as possible or a sufficient cooling, with the result that a reduction of the contact resistance is particularly advantageous. However, the invention enables the contact resistance to be advantageously reduced also in the case of other semiconductor components with a patterned surface.

Other features which are considered as characteristic for the invention are set forth in the appended claims.

Although the invention is illustrated and described herein as embodied in a method for fabricating a semiconductor component based on a nitride compound semiconductor, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1A to 1I are diagrammatic, sectional views illustrating a fabrication method for producing an exemplary embodiment according to the invention; and

FIG. 2 is a graph showing a current-voltage characteristic curve of a semiconductor component fabricated according to the invention in comparison with a component according to the prior art.

### DESCRIPTION OF THE PREFERRED EMBODIMENTS

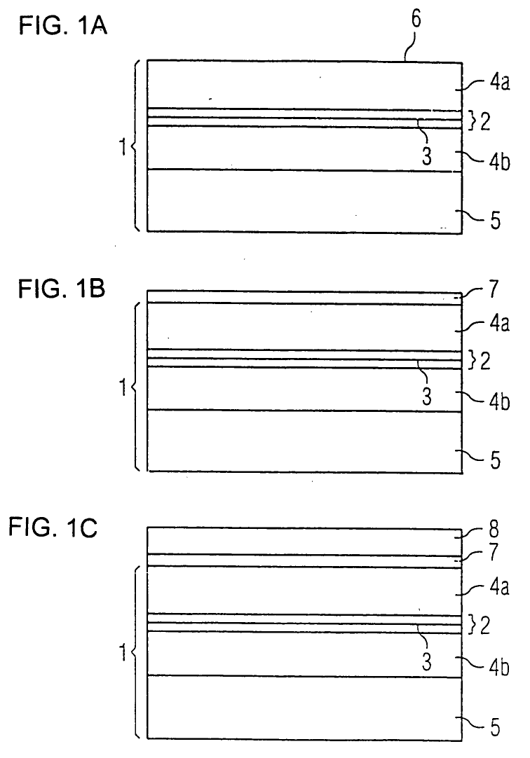

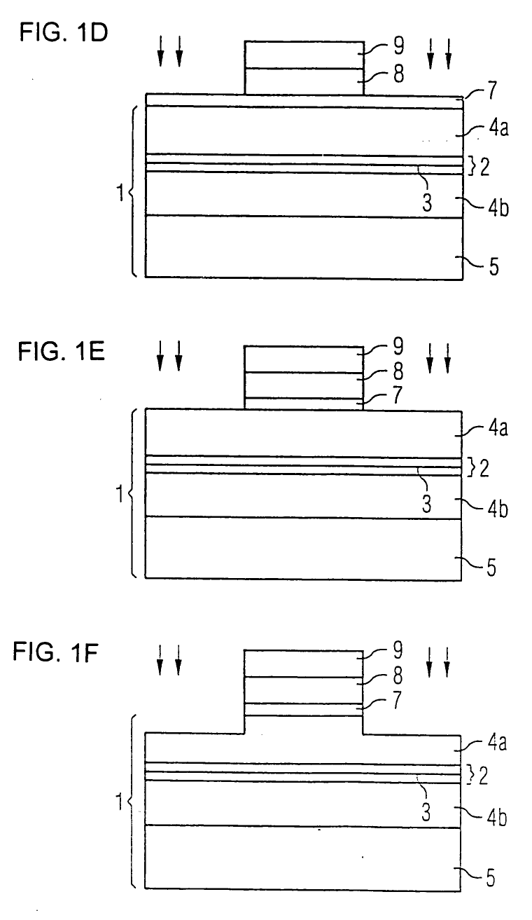

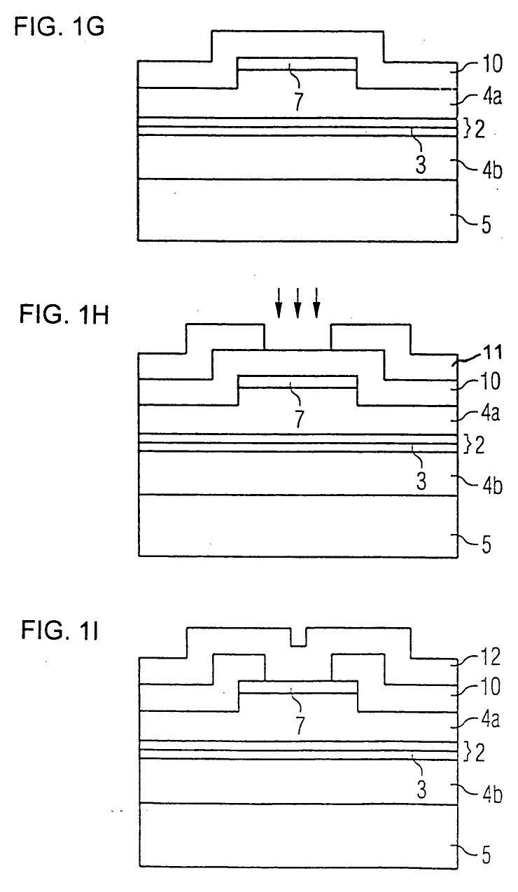

In all the figures of the drawing, sub-features and integral parts that correspond to one another bear the same reference symbol in each case. Referring now to the figures of the drawing in detail and first, particularly, to FIG. 1A thereof, there is shown a first step of a fabrication method for producing a semiconductor body 1 based on nitride compound semiconductors. The semiconductor body 1 may contain for example an active, radiation-generating layer 2, preferably with a quantum well structure 3, and also further nitride compound semiconductor layers 4a, 4b, which are applied to a substrate 5. In this case, the substrate 5 is considered to be part of the semiconductor body 1, it not being necessary for the substrate 5 itself to be a semiconductor. The active layer 2 may have for example a quantum well structure 3 with one or more InGaN layers, downstream of which are disposed, on one or both sides, the GaN or AlGaN layers 4a, 4b as waveguide and/or cladding layers.

The semiconductor layers are preferably deposited epitaxially on the substrate 5. SiC substrates, sapphire substrates and GaN substrates, in particular, are suitable for this in the case of nitride compound semiconductors. In the present case, the substrate 5 is made of n-doped SiC or GaN.

In the exemplary embodiment, a laser ridge with a p-type contact area of the semiconductor layers that is metallized over the whole area is preferably fabricated.

In order to form a radiation-generating pn junction, in the exemplary embodiment, the semiconductor layer 4b disposed between the active layer 2 and the substrate 5 is n-doped, for example with silicon, and the opposite layer 4b with respect to the active layer 2 is p-doped, for example with magnesium or zinc.

In the next step, a metal layer 7 is deposited on that surface of the semiconductor body 6 which is remote from the substrate 5, FIG. 1B. The metal layer 7 may be for example a platinum layer having a thickness of between 5 nm and 500 nm, preferably between 40 nm and 120 nm, layer thicknesses of about 100 nm have proved to be advantageous.

A dielectric mask 8, for example made of SiO₂, is subsequently formed on the metal layer. For this purpose, first a continuous mask layer, for example an SiO₂ layer having a thickness of 500 nm, is applied to the metal layer 7, FIG. 1C. The mask may be fabricated by a conventional photolithographic method, by application of a photoresist 9, exposure, development of the photoresist, removal of the exposed or unexposed regions (depending on whether a positive or negative resist is used) and removal, for example etching-away, of the regions of the mask layer 8 that are not covered with the photoresist, FIG. 1D.

The semiconductor body 1 is subsequently patterned. For this purpose, parts of the metal layer 7 that are not covered with the mask 8 are removed (FIG. 1E) and then parts of the underlying semiconductor body are removed (FIG. 1F).

The dielectric mask 8 may contain for example aluminum oxide, silicon nitride, titanium oxide, Ta oxide and/or zirconium oxide.

The metal layer 7 is etched away or removed by sputtering-back, for example. By way of example, wet-chemical etching methods or RIE methods are suitable for partly removing the adjoining semiconductor layer 4b.

The metal layer and the semiconductor layer are particularly preferably removed by a dry etching method. For this purpose, the photoresist layer is preferably still situated on the dielectric mask.

In the exemplary embodiment shown, the semiconductor layer is essentially removed in a perpendicular direction with respect to the layer plane. In order to form a waveguide ridge, the mask 8 is embodied in strip form in plan view (not illustrated). An elongate, parallelepiped-like semiconductor structure is thus shaped by the removal on that side of the layer 4b that is remote from the substrate, the semiconductor structure forming the aforementioned ridge waveguide.

In the next step, a passivation layer 10, for example made of a silicon oxide or a silicon nitride, is applied to the semiconductor body, FIG. 1G. In this case, first a continuous passivation layer 10 is deposited. In order to form an opening in the passivation layer 10 to the metal layer 7, the passivation layer 10 is provided with a further mask 11, for example a photoresist mask, parts of the passivation layer 10 not being covered with the mask 11 in regions in which the passivation layer adjoins the metal layer 7. The mask 11 may be fabricated by a photolithographic method, by way of example, as already described, FIG. 1H.

In the regions not covered by the mask 11, the passivation layer 10 is then removed, for example etched away, so that the metal layer 7 is at least partly uncovered. The mask 11 is then removed.

In order to conclude the method, a contact metallization 12 is applied in large-area fashion on that side of the semiconductor body which is remote from the substrate, FIG. 1I. The contact metallization 12 is in direct contact with the metal layer 7 at least in partial regions and partly also covers the surface of the passivation layer 10.

The contact metallization 12 forms an electrical connection area of the component, via which, in conjunction with the metal layer 7, a current can be impressed into the component during operation. The large-area embodiment facilitates the formation of an electrical connection. In comparison with this, a direct connection to the metal layer 7 would, if possible, require a significantly higher lateral positioning accuracy. Moreover, the material selection for the metal layer would be restricted to a greater extent, since the metal layer is intended, on the one hand, to form a good electrical and mechanical contact with the semiconductor body and, on the other hand, to have advantageous connection properties (bonding properties) with regard to an electrical connection.

By contrast, the contact metallization 12 can be optimized in particular with regard to an electrical connection that is to be provided later. The contact metallization is preferably applied in a plurality of non-illustrated layers. In this case, it is possible to combine for example a titanium layer as an adhesion promoter, a palladium or platinum layer as diffusion barrier and a gold layer, which forms the connection surface, as the contact metallization 12.

The method shown in FIGs. 1A-1I has been explained using an individual semiconductor body for the sake of clarity. It is advantageous that the method can also be carried out in the context of the production process with semiconductor bodies that have not yet been singulated and are joined together in the wafer. More widely, it is also possible for individual steps or sequences of steps of the method, in particular the application of the metal layer and the subsequent patterning, to be effected with the semiconductor body joined together in the wafer and for the remaining steps to be carried out on singulated semiconductor bodies.

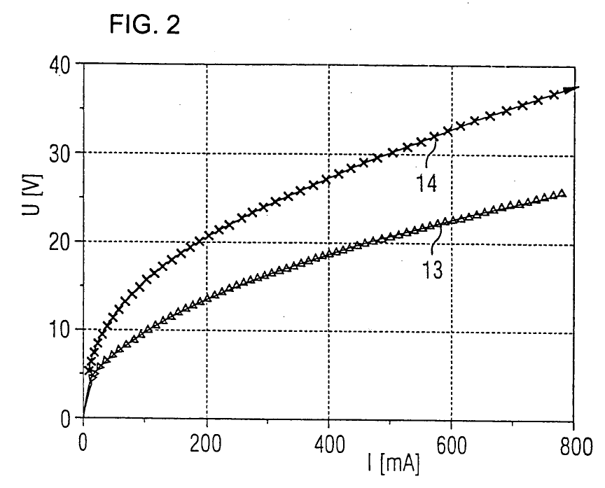

FIG. 2 illustrates current-voltage characteristic curves of a component fabricated according to the invention in comparison with a component according to the prior art. The characteristic curves were measured on gallium-nitride-based laser diodes with a ridge waveguide (ridge width 5 μm, ridge lengths 600 μm). In the case of the component according to the invention, the metal layer, according to FIG. 1A-1I, was applied to the p-conducting side of the semiconductor body before the ridge patterning, whereas it was applied after the opening of the passivation layer in the case of the component according to the prior art.

The voltage U dropped across the laser diode is in each case plotted as a function of an impressed operating current I. A line 13 and the associated measurement points represent the measurement result for the laser diode according to the invention, and line 14 and the associated measurement points represent the measurement result for the laser diode according to the prior art.

In the entire measurement range, the voltage U assigned to a given current I is significantly lower in the case of the invention than in the case of the component according to the prior art. The component according to the invention thus also has an advantageously reduced resistance U/I, which is essentially determined by the p-side contact resistance.

It goes without saying that the explanation of the invention on the basis of the exemplary embodiments described is not to be understood as a restriction of the invention thereto. More widely, the invention is not restricted to nitride compound semiconductors and can also be used in the case of components with semiconductor bodies of other semiconductor material systems which may contain for example GaAs, GaP, InP, InAs, AlGaP, AlGaAs, GaAlSb, InGaAs, InGaAsP, InGaAlP, GaAlSbP, ZnSe or ZnCdSe.

We claim:

1. A method for fabricating a semiconductor component, which comprises the steps of:
providing a semiconductor body containing a substrate and at least one nitride compound semiconductor disposed on the substrate;
applying a metal layer to a surface of the semiconductor body; and
dry-chemically removing a part of the metal layer and a part of the semiconductor body previously covered by the removed metal layer.

2. The method according to claim 1, which further comprises forming the nitride compound semiconductor as a compound having a formula Al_{y}InₓGa_{1-x-y}N, 0≦x≦1, 0≦y≦1, 0≦x+y≦1.

3. The method according to claim 1, wherein the dry-chemically removing step is preformed by the steps of:
forming a mask on the metal layer, a part of the metal layer not being covered by the mask;
removing that part of the metal layer which is not covered by the mask, a part of the surface of the semiconductor body thereby being uncovered and defining an uncovered surface;
partially removing the semiconductor body in regions of the uncovered surface; and
removing the mask.

4. The method according to claim 3, which further comprises forming the mask as a dielectric mask which contains at least one material selected from the group consisting of silicon oxide, aluminum oxide, silicon nitride, titanium oxide, Ta oxide, zirconium oxide, and a layer system containing at least one of the materials.

5. The method according to claim 3, which further comprises fabricating the mask photolithographically, in which a photoresist mask is fabricated on the mask.

6. The method according to claim 1, which further comprises removing the metal layer by a sputtering-back method.

7. The method according to claim 1, which further comprises removing the part of the semiconductor body by an etching method.

8. The method according to claim 1, which further comprises applying a passivation layer to the surface of the semiconductor body and part of the metal layer, at least a further part of the metal layer not being covered by the passivation layer.

9. The method according to claim 8, wherein the step of applying the passivation layer further comprises the steps of:
applying the passivation layer as a continuous passivation layer to the surface of the semiconductor body and the part of the metal layer;
applying a mask on the continuous passivation layer, the mask not covering the passivation layer at least in a region in which the passivation layer adjoins the metal layer;
removing parts of the passivation layer which are not covered with the mask; and
removing the mask.

10. The method according to claim 8, which further comprises forming the passivation layer to contain a silicon oxide.

11. The method according to claim 9, which further comprises fabricating the mask photolithographically.

12. The method according to claim 1, which further comprises applying a contact metallization.

13. The method according to claim 1, which further comprises forming the metal layer to contain a material selected from the group consisting of platinum and palladium.

14. The method according to claim 1, which further comprises forming a thickness of the metal layer to be between 5 nm and 500 nm.

15. The method according to claim 1, which further comprises forming the semiconductor body to be p-doped in a region adjoining the metal layer.

16. The method according to claim 15, which further comprises doping the p-doped region of the semiconductor body with a material selected from the group consisting of magnesium and zinc.

17. The method according to claim 3, which further comprises forming the semiconductor body with a radiation-generating active layer.

18. The method according to claim 17, wherein a semiconductor ridge structure is shaped by the partially removing of the semiconductor body step.

19. The method according to claim 18, wherein the semiconductor ridge structure forms a waveguide at least for parts of radiation generated by the active layer.

20. The method according to claim 17, wherein the semiconductor component is a luminescence diode.

21. The method according to claim 20, wherein the luminescence diode is selected from the group consisting of light-emitting diodes, laser diodes, and laser diodes with a ridge waveguide.

22. The method according to claim 2, which further comprises forming the substrate to be n-conducting.

23. The method according to claim 22, which further comprises forming the substrate to be selected from the group consisting of n-doped SiC and n-doped GaN.

24. The method according to claim 1, which further comprises forming a thickness of the metal layer to be between 40 nm and 120 nm.

25. The method according to claim 1, which further comprises removing the metal layer by an etching method.
